(19) United States
(12) Patent Application Publication
(10) Pub. No.: US 2020/0235198 A1
(43) Pub. Date: Jul. 23, 2020

(54) SEMICONDUCTOR DEVICE

(71) Applicant: SUMITOMO ELECTRIC DEVICE INNOVATIONS, INC., Kanagawa (JP)

(72) Inventor: Takeshi Igarashi, Yokohama-shi (JP)

(73) Assignee: SUMITOMO ELECTRIC DEVICE INNOVATIONS, INC., Kanagawa (JP)

(21) Appl. No.: 16/743,963

(22) Filed: Jan. 15, 2020

(30) Foreign Application Priority Data
Jan. 18, 2019 (JP) 2019-006710

(51) Int. Cl. H01L 49/02

(52) U.S. Cl. CPC H01L 28/65

(57) ABSTRACT

An MIM capacitor of a semiconductor device is configured to include a dielectric layer between a lower electrode and an upper electrode, and a floating electrode provided in the dielectric layer, extended in parallel to the upper electrode and the lower electrode, and not electrically connected from any one of the lower electrode and the upper electrode is included.

### BACKGROUND OF THE INVENTION

### 1. Filed of the Invention

The present disclosure relates to a semiconductor device.

### 2. Background Arts

In some cases, when a high electron mobility transistor (HEMT) is to be formed, a stacked type capacitor is provided. For example, Japanese Unexamined Patent Publication No. 2014-56887 discloses a method of manufacturing a capacitor (MIM capacitor) of a metal insulator metal (MIM) structure having a lower electrode, a dielectric film, and an upper electrode provided on a semiconductor substrate.

Herein, in some cases, some MIM capacitors may fail in a short period during actual use. As a cause of the failure, it is considered that, when an integrated circuit chip including the MIM capacitor is implemented in a package or the like, the dielectric film of the MIM capacitor is peeled off from the electrode, and thus, partial discharge occurs in the peeled place, so that dielectric breakdown (all-path breakdown) finally occurs.

An object of one aspect of the present disclosure is to suppress an occurrence of partial discharge in a place where a dielectric layer of an MIM capacitor is peeled off.

### SUMMARY OF THE INVENTION

According to one aspect of the present disclosure, there is provided a semiconductor device including: a metal insulator metal (MIM) capacitor configured to include a dielectric layer between a lower electrode and an upper electrode; and a floating electrode provided in the dielectric layer, extended in parallel to the upper electrode and the lower electrode, and not electrically connected from any one of the lower electrode and the upper electrode.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 is a cross sectional view illustrating a semiconductor device according to an aspect of the present disclosure.

FIG. 2A is a diagram describing a method of manufacturing the semiconductor device illustrated in FIG. 1.

FIG. 2B is a diagram describing the method of manufacturing the semiconductor device illustrated in FIG. 1.

FIG. 3A is a diagram describing the method of manufacturing the semiconductor device illustrated in FIG. 1.

FIG. 3B is a diagram describing the method of manufacturing the semiconductor device illustrated in FIG. 1.

FIG. 4A is a diagram describing the method of manufacturing the semiconductor device illustrated in FIG. 1.

FIG. 4B is a diagram describing the method of manufacturing the semiconductor device illustrated in FIG. 1.

FIG. 4C is a diagram describing the method of manufacturing the semiconductor device illustrated in FIG. 1.

FIG. 5 is a diagram schematically illustrating an MIM capacitor according to Comparative Example.

FIG. 6 is a diagram schematically illustrating an MIM capacitor of the semiconductor device according to the aspect of the present disclosure.

### DESCRIPTION OF EMBODIMENTS

Specific examples of a semiconductor device according to an embodiment of the present disclosure will be described with reference to the drawings. In addition, in the description, the same elements or elements having the same functions are denoted by the same reference numerals, and redundant description will be omitted. The present disclosure is not limited to the following examples and is intended to be indicated by the claims and to include all the modifications within the intention and scope of the claims and the equivalents thereof.

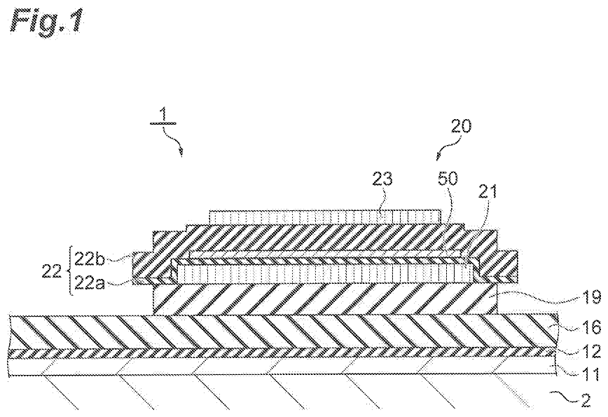

FIG. 1 is a cross sectional view illustrating a semiconductor device 1 according to the present embodiment. The semiconductor device 1 is provided on the substrate 2 and is configured to include a transistor (not illustrated) and an MIM capacitor 20. The Transistor (not illustrated) and the MIM capacitor 20 included in the semiconductor device 1 are provided at different places on the substrate 2. FIG. 1 illustrates the place in the semiconductor device 1 where the MIM capacitor 20 is provided. Hereinafter, the MIM capacitor 20 in the configuration of the semiconductor device 1 will be mainly described, and the transistor (not illustrated) will be omitted in description. The substrate 2 is a substrate for crystal growth. As the substrate 2, for example, an SiC substrate, a GaN substrate, a sapphire (Al₂O₃) substrate, or the like is exemplified. In the present embodiment, the substrate 2 is an SiC substrate. Hereinafter, in some cases, a direction in which the respective components included in the semiconductor device 1 are stacked is referred to as a stacking direction, and a direction orthogonal to the stacking direction is referred to as a horizontal direction.

The semiconductor device 1 is configured to include a semiconductor stacked body 11, a passivation film 12, an insulating film 16, a silicon dioxide film 19, and the MIM capacitor 20 in order from the substrate 2 side.

The semiconductor stacked body 11 is a stacked body of semiconductor layers epitaxially grown on the substrate 2. The semiconductor stacked body 11 includes, for example, a buffer layer, a channel layer, a barrier layer, and a cap layer in order from the surface of the substrate 2. The transistor (not illustrated) included in the semiconductor device 1 according to the present embodiment is, for example, a high electron mobility transistor (HEMT), and two-dimensional electron gas (2DEG) occurs in a channel layer side of an interface between the channel layer and the barrier layer, so that a channel region is formed in the channel layer. The buffer layer is, for example, an AlN layer; the channel layer is, for example, a GaN layer; the barrier layer is, for example, an AlGaN layer; and the cap layer is, for example, a GaN layer.

The passivation film 12 is a protective film for protecting the surface of the semiconductor stacked body 11 and is provided on the semiconductor stacked body 11. The passivation film 12 may include, for example, a first insulating film and a second insulating film. From the point of view of allowing etching resistance of the first insulating film to be higher than that of the second insulating film, in some cases, the first insulating film is formed according to a low pressure chemical vapor deposition (LPCVD) method. The LPCVD method is a method of forming a dense film by lowering a film-formation pressure and increasing a film-formation temperature. The lower limit of the thickness of the first insulating film is, for example, 10 nm, and the upper limit thereof is, for example, 50 nm. The second insulating film is provided on the first insulating film. From the point of view of allowing etching resistance of the second insulating film to be lower than that of the first insulating film, the second insulating film may be formed according to a plasma CVD method. Since the film-formation temperature in the plasma CVD method is lower than the film-formation temperature in the LPCVD method, the second insulating film is sparser in film quality than the first insulating film. The Si composition of the second insulating film is smaller than the Si composition of the first insulating film. In addition, the refractive index of the second insulating film is smaller than the refractive index of the first insulating film. The lower limit of the thickness of the second insulating film is, for example, 30 nm, and the upper limit thereof is, for example, 500 nm.

The insulating film 16 is an insulating film provided on the passivation film 12. The thickness of the insulating film 16 is, for example, 150 nm or more and 400 nm or less. In the present embodiment, the insulating film 16 is a silicon nitride film. The insulating film 16 covers the surface of the semiconductor stacked body 11 (specifically, on the passivation film) and is located between the semiconductor stacked body 11 and the MIM capacitor 20. In addition, the insulating film 16 insulates the gate of the transistor (not illustrated) and the field plate.

The silicon dioxide film 19 is an insulating film serving as a base film of the MIM capacitor 20. Since the silicon dioxide film 19 is provided, the distance between the substrate 2 and a lower electrode 21 (the details will be described later) of the MIM capacitor 20 is increased, so that the leakage current from the lower electrode 21 to the substrate 2 can be reduced. The thickness of the silicon dioxide film 19 is, for example, 100 nm or more and 400 nm or less.

The MIM capacitor 20 includes the lower electrode 21, a dielectric layer 22, and an upper electrode 23 that are sequentially stacked along the stacking direction. That is, the MIM capacitor 20 is configured to include the dielectric layer 22 between the lower electrode 21 and the upper electrode 23.

The lower electrode 21 is a conductive layer located on the lower side (substrate 2 side) of the MIM capacitor 20 and is provided on the silicon dioxide film 19. The lower electrode 21 is, for example, a gold-based metal layer. More specifically, the lower electrode 21 is a metal layer containing, for example, titanium and tungsten, and the upper surface (surface in contact with the dielectric layer 22) is made of gold. The lower electrode 21 may have a single layer structure or may have a multilayer structure. The thickness of the lower electrode 21 is, for example, 100 nm or more and 400 nm or less.

The dielectric layer 22 is located between the lower electrode 21 and the upper electrode 23. The thickness of the dielectric layer 22 is, for example, 50 nm or more and 400 nm or less. The dielectric layer 22 includes a lower dielectric layer 22a, an upper dielectric layer 22b, and a floating electrode 50. The floating electrode 50 is provided in the dielectric layer 22.

The lower dielectric layer 22a is an insulating film covering the lower electrode 21. The lower dielectric layer 22a is made of, for example, a silicon nitride film. The lower dielectric layer 22a is also in contact with the silicon dioxide film 19 as well as the lower electrode 21, and the lower electrode 21 is sealed by the lower dielectric layer 22a and the silicon dioxide film 19. The thickness of the lower dielectric layer 22a is, for example, 10 nm or more and 80 nm or less. An end portion (end portion in the horizontal direction) of the lower dielectric layer 22a protrudes outward from the side surface of the silicon dioxide film 19 in the horizontal direction, and the side surface of the silicon dioxide film 19 is exposed. For this reason, the end portion of the lower dielectric layer 22a becomes an eave to the silicon dioxide film 19 to be separated from the insulating film 16. Thus, the leakage current from the dielectric layer 22 to the substrate 2 through the insulating film 16 can be reduced. The end portion of the lower dielectric layer 22a protrudes from the side surface of the silicon dioxide film 19 within a range of, for example, 0.5 μm or more and 2 μm or less. In this case, it is possible to achieve the reduction effect of the leakage current while securing the structural strength of the end portion. The range may be of 0.5 μm or more and 1.0 μm or less.

The floating electrode 50 is a conductive layer provided on the lower dielectric layer 22a. The floating electrode 50 is made of a material containing no gold and is a metal layer containing, for example, Ti. The floating electrode 50 may have a single layer structure or may have a multilayer structure. The thickness of the floating electrode 50 is, for example, 3 nm or more and 10 nm or less. The floating electrode 50 is extended in parallel to the lower electrode 21 and the upper electrode 23 and is not electrically connected from any one of the lower electrode 21 and the upper electrode 23. The floating electrode 50 is provided near the lower electrode 21. That is, the distance between the floating electrode 50 and the lower electrode 21 is smaller than the distance between the floating electrode 50 and the upper electrode 23. As an example, it is set that the distance between the floating electrode 50 and the lower electrode 21: the distance between the floating electrode 50 and the upper electrode 23=1:9. The distance between the floating electrode 50 and the lower electrode 21 is set to be, for example, 1/10 or less of the total thickness of the dielectric layer 22. When viewed from the stacking direction, the regions of the lower dielectric layer 22a and the upper dielectric layer 22b of the dielectric layer 22 include the region of the lower electrode 21, the region of the lower electrode 21 includes the region of the floating electrode 50, and the region of the floating electrode 50 includes the region of the upper electrode 23. In addition, the region of the floating electrode 50 may include the region of the lower electrode 21 when viewed from the stacking direction.

The upper dielectric layer 22b is an insulating film covering the floating electrode 50. The upper dielectric layer 22b is made of, for example, a silicon nitride film. The upper dielectric layer 22b is in contact with the lower dielectric layer 22a as well as the floating electrode 50, and the floating electrode 50 is sealed by the lower dielectric layer 22a and the upper dielectric layer 22b. The thickness of the upper dielectric layer 22b is, for example, 50 nm or more and 400 nm or less.

The upper electrode 23 is a conductive layer located on the upper side of the MIM capacitor 20 and is provided on the upper dielectric layer 22b. The upper electrode 23 may overlap the entire lower electrode 21 or may overlap a portion of the lower electrode 21. The upper electrode 23 is, for example, a gold-based metal layer. More specifically, the upper electrode 23 is a metal layer containing, for example, titanium and tungsten, and the upper surface thereof is made of gold. The upper electrode 23 may have a single layer structure or may have a multilayer structure. The thickness of the upper electrode 23 is, for example, 100 nm or more and 400 nm or less.

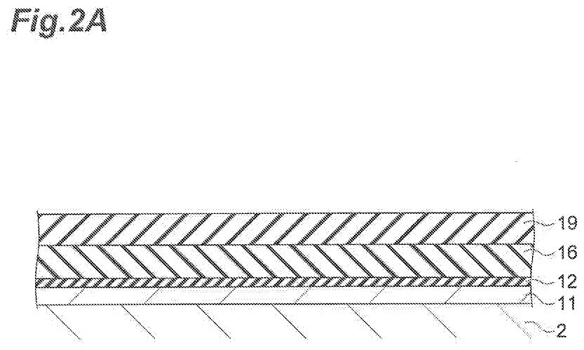

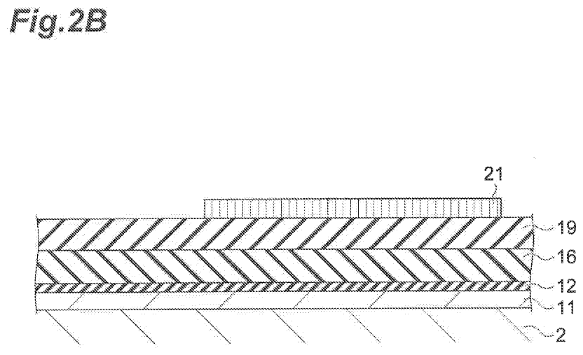

Next, an example of a method of manufacturing the semiconductor device 1 according to the present embodiment will be described with reference to FIGS. 2A to 4C. FIGS. 2A, 2B, 3A, 3B, 4A, 4B, and 4C are diagrams describing the method of manufacturing the semiconductor device 1 according to the present embodiment.

First, as illustrated in FIG. 2A, the semiconductor stacked body 11, the passivation film 12, the insulating film 16, and the silicon dioxide film 19 are sequentially formed on the substrate 2 (first step). In the first step, first, by a metal organic chemical vapor deposition (MOCVD) method, the semiconductor stacked body 11 is grown on the substrate 2. Subsequently, before the completion of formation of the transistor (not illustrated), the passivation film 12 is formed to cover the substrate 2 on which the semiconductor stacked body 11 is grown. In forming the passivation film 12, the first insulating film according to the LPCVD method and the second insulating film according to the plasma CVD method may be formed. The second insulating film is provided so as to cover the ohmic electrode. In the case of performing the LPCVD method, the film-formation temperature is, for example, 800° C. or more and 900° C. or less, and the film-formation pressure is, for example, 10 Pa or more and 100 Pa or less. In the case of performing the plasma CVD method, the film-formation temperature is, for example, 300° C. or more and 350° C. or less, and the film-formation pressure is, for example, 50 Pa or more and 200 Pa or less.

Subsequently, the insulating film 16 that is a silicon nitride film is formed according to, for example, the plasma CVD method. Subsequently, the silicon dioxide film 19 is formed according to, for example, a sputtering vapor deposition method.

Subsequently, as illustrated in FIG. 2B, the lower electrode 21 is formed on the silicon dioxide film 19 (second step). In the second step, the lower electrode 21 patterned according to a vapor deposition method and lift-off by using a resist pattern (not illustrated) is formed. The thickness of the lower electrode 21 is set to, for example, 100 nm or more and 400 nm or less.

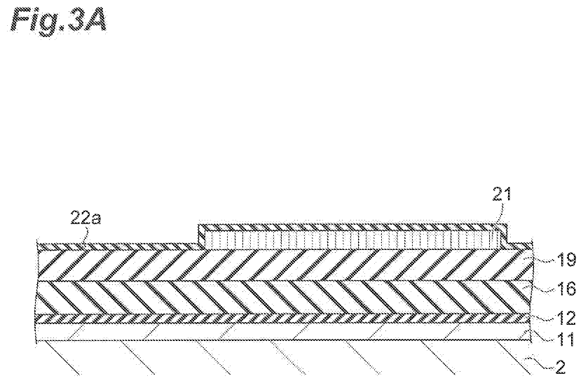

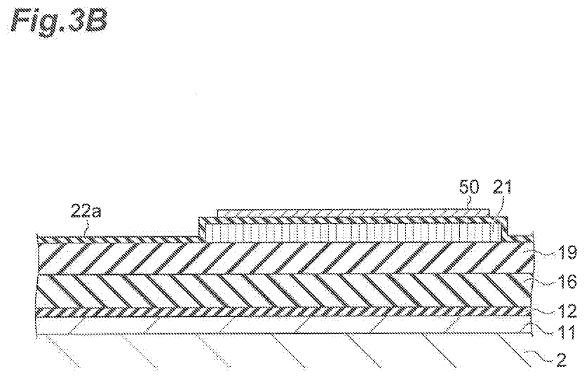

Subsequently, as illustrated in FIG. 3A, the lower dielectric layer 22a that is a silicon nitride film is formed on the lower electrode 21 according to the plasma CVD method (third step). The lower dielectric layer 22a is formed so as to be in contact with the silicon dioxide film 19 as well as the lower electrode 21. The thickness of the lower dielectric layer 22a is set to, for example, 10 nm or more and 80 nm or less.

Subsequently, as illustrated in FIG. 3B, the floating electrode 50 is formed on the lower dielectric layer 22a (fourth step). In the fourth step, the floating electrode 50 patterned according to a vapor deposition method and lift-off by using a resist pattern (not illustrated) is formed. The thickness of the floating electrode 50 is set to, for example, 3 nm or more and 10 nm or less.

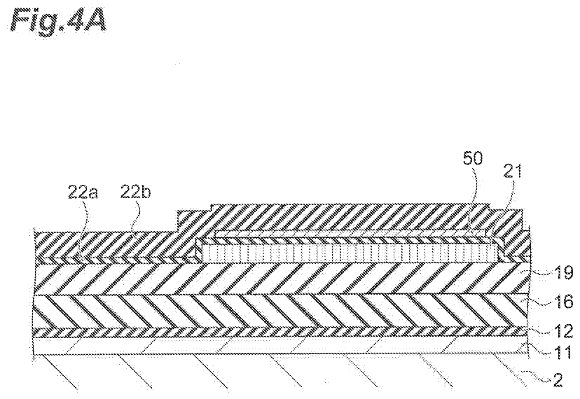

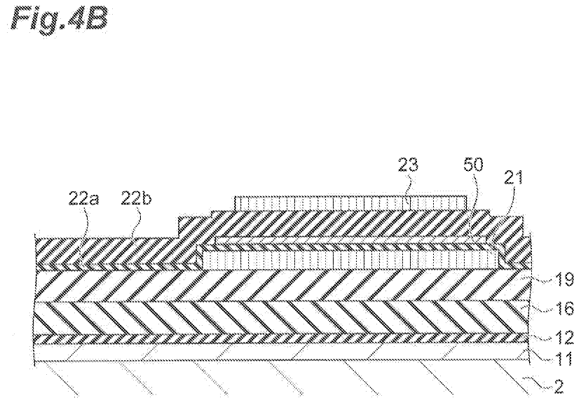

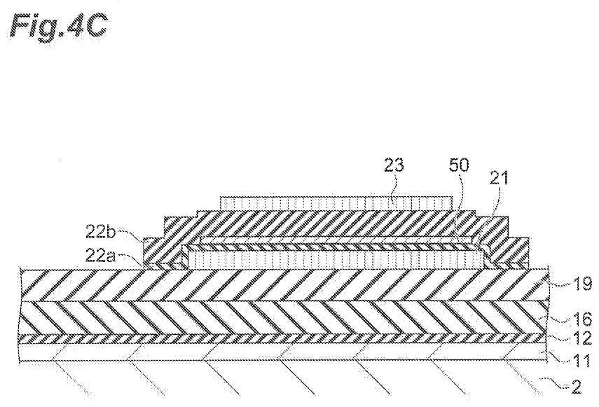

Subsequently, as illustrated in FIG. 4A, the upper dielectric layer 22b that is a silicon nitride film is formed on the floating electrode 50 according to the plasma CVD method (fifth step). The upper dielectric layer 22b is formed so as to be in contact with the lower dielectric layer 22a as well as the floating electrode 50. The thickness of the upper dielectric layer 22b is set to, for example, 50 nm or more and 400 nm or less.

Subsequently, as illustrated in FIG. 4B, the upper electrode 23 is formed on the upper dielectric layer 22b (sixth step). In the sixth step, the upper electrode 23 patterned according to a vapor deposition method and lift-off by using a resist pattern (not illustrated) is formed. The thickness of the upper electrode 23 is set to, for example, 100 nm or more and 400 nm or less.

Subsequently, by forming a resist pattern (not illustrated) on the dielectric layer 22 and performing dry etching using a fluorine-based gas, as illustrated in FIG. 4C, the dielectric layer 22 exposed from the resist pattern (not illustrated) is removed (the seventh step). The silicon dioxide film 19 is provided just below the dielectric layer 22. Herein, the etching rate for the silicon nitride by the fluorine-based gas is greatly larger than the etching rate for the silicon oxide. For this reason, the silicon dioxide film 19 functions as an etching stopper for dry etching in the seventh step. The dry etching is, for example, reactive ion etching (RIE). As the fluorine-based gas, one or more is selected from a group consisting of, for example, SF₆, CF₄, CHF₃, C₃F₆, and C₂F₆. The RIE apparatus may be of an inductive coupled plasma (ICP) type.

Finally, by wet-etching the silicon dioxide film 19 on the insulating film 16 (the eighth step), the semiconductor device 1 illustrated in FIG. 1 is manufactured. In the eighth step, the silicon dioxide film 19 is patterned, and the wet etching is performed by a buffered hydrofluoric acid which is a hydrofluoric acid based solution. In the case of using the buffered hydrofluoric acid as a hydrofluoric acid based solution, for example, the etching rate of the silicon oxide film is about 300 nm/min, and the etching rate of the silicon nitride film is about 10 nm/min. In the eighth step, since the wet etching which is isotropic etching is performed, the silicon dioxide film 19 is side-etched. In the eighth step, similarly, the dielectric layer 22 is also side-etched. In view of the difference between the etching rates described above, the side-etched amount of the silicon dioxide film 19 is greatly larger than the side-etched amount of the dielectric layer 22 (refer to FIG. 1). For this reason, after the eighth step, the end portion of the dielectric layer 22 becomes an eave to the silicon dioxide film 19. The side surface of the lower electrode 21 is covered by the dielectric layer 22, so that the lower electrode 21 is protected.

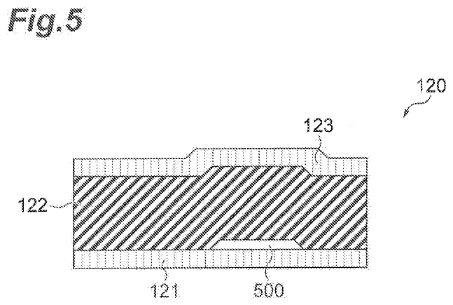

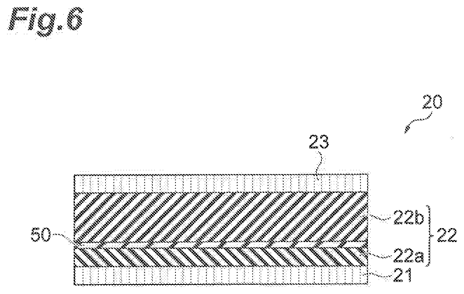

Hereinafter, while comparing with an MIM capacitor of a semiconductor device according to Comparative Example, the function and effect of the MIM capacitor 20 of the semiconductor device 1 according to the present embodiment will be described. FIG. 5 is a diagram schematically illustrating the MIM capacitor 120 of the semiconductor device according to Comparative Example. FIG. 6 is a diagram schematically illustrating the MIM capacitor 20 of the semiconductor device 1 according to the present embodiment.

As illustrated in FIG. 5, the MIM capacitor 120 of the semiconductor device according to Comparative Example is configured to include a lower electrode 121, an upper electrode 123, and a dielectric layer 122 provided between the lower electrode 121 and the upper electrode 123. Herein, when an integrated circuit chip including the MIM capacitor 120 is implemented in a package or the like, in some cases, the dielectric layer 122 is peeled off from the electrode due to thermal stress. Such peeling remarkably occurs, for example, in the lower electrode 121 of which the surface in contact with the dielectric layer 122 is made of gold (that is, adhesion to the dielectric layer 122 is low). It is considered that the place where the dielectric layer 122 is peeled off becomes a void 500, and the partial discharge occurs in the void 500, so that dielectric breakdown (all-path breakdown) finally occurs. As the voltage applied to the void 500 becomes larger, the partial discharge is easily to occur.

Considering the region in which the void 500 occurs, since charges generated by the voltage application do not move in the dielectric layer, this structure is equivalent to a series connection of two capacitors including a capacitor configured with the dielectric layer 122 and a capacitor configured with the void. Then, the voltage applied between the lower electrode 121 and the upper electrode 123 is distributed to the two capacitors, and thus, charges stored in each of the capacitors become equal. In a case where a relative dielectric constant=8 and a film thickness=200 nm are set as the characteristics of the dielectric layer 122, a relative dielectric constant=1 and a void interval=25 nm are set as the characteristics of the void 500, and a voltage of 10 V is applied between the upper and lower electrodes, the equal voltages of 5 V are calculated to be distributed to the dielectric layer 122 and the void 500. At this time, a large electric field of 2×108 V/m (0.2 V/nm) is generated in the void, and thus, the possibility that the partial discharge occurs becomes high.

In contrast, as illustrated in FIG. 6, the MIM capacitor 20 of the semiconductor device 1 according to the present embodiment is configured to include the dielectric layer 22 between the lower electrode 21 and the upper electrode 23, and the dielectric layer 22 includes the floating electrode 50 which is extended in parallel to the lower electrode 21 and the upper electrode 23 and not electrically connected from any one of the lower electrode 21 and the upper electrode 23. Then, the distance between the floating electrode 50 and the lower electrode 21 is smaller than the distance between the floating electrode 50 and the upper electrode 23.

Thus, in the MIM capacitor 20 according to the present embodiment, the floating electrode 50 not electrically connected from the lower electrode 21 and the upper electrode 23 is provided on the dielectric layer 22 provided between the lower electrode 21 and the upper electrode 23. The floating electrode 50 described above is provided in the dielectric layer 22, that is, between the lower electrode 21 and the upper electrode 23, and thus, the distance of the electrode (in this case, the floating electrode 50) from the void generated, for example, by the peeling of the dielectric layer 22 is shortened, and the voltage applied to the void can be suppressed, so that it is possible to suppress the occurrence of the partial discharge in the void. As described above, in the MIM capacitor 20, a material (for example, gold) having a low degree of adhesion to the dielectric layer may be used for the upper surface of the electrode, and thus, the void described above is likely to be generated in the interface with the lower electrode 21 in the dielectric layer 22. In this respect, since the distance between the floating electrode 50 and the lower electrode 21 is set to be smaller than the distance between the floating electrode 50 and the upper electrode 23, the floating electrode 50 can be provided near the lower electrode 21 where the void is likely to be generated, and thus, the distance from the void to the electrode (in this case, the floating electrode 50) is more appropriately shortened, so that it is possible to more appropriately suppress the voltage applied to the void. As described above, according to the semiconductor device 1 according to the present embodiment, it is possible to suppress the occurrence of the partial discharge in the place where the dielectric layer 22 of the MIM capacitor 20 is peeled off.

As an example, similarly to Comparative Example described above, the case is considered with a relative dielectric constant of the dielectric layer 22 formed by the silicon nitride film =8, the film thickness=200 nm, a relative dielectric constant of the void which is air=1, and a void interval=25 nm. For example, in a case where the floating electrode 50 is provided at a position by 20 nm separated from the lower end (that is, the place in contact with the lower electrode 21) of the dielectric layer 22, the voltage applied to the void is about 0.09 times the voltage applied to the entire capacitor. When the voltage Vo applied to the capacitor is set to be 10 V, the voltage of the void becomes about 0.9 V, and the electric field becomes about 0.04 V/nm. As described in Comparative Example described above, in a case where the floating electrode 50 is not provided, under the same conditions, 5 V is applied to the void (electric field is 0.2 V/nm), and thus, it can be understood that it is possible to suppress the occurrence of the partial discharge by providing the floating electrode 50.

In addition, in a case where a void is generated by peeling off a portion of a minute region of the dielectric layer, since the capacitance of the MIM capacitor is not almost changed, the integrated circuit operates without problem, and thus, practically, it is difficult to detect the peeling of the dielectric layer from the electric characteristics. For this reason, in the related art, it has been difficult to prevent the failure according to the time variation of the MIM capacitor caused by the peeling of the dielectric layer.

In this respect, as in the MIM capacitor 20 of the semiconductor device 1 according to the present embodiment, by employing the configuration capable of suppressing the occurrence of the partial discharge even in the generation of the void by providing the floating electrode 50, it is possible to prevent an early failure of the MIM capacitor.

In the MIM capacitor 20 of the semiconductor device 1 according to the present embodiment, the distance between the floating electrode 50 and the lower electrode 21 is 1/10 or less of the thickness of the dielectric layer 22. Thus, the floating electrode 50 can be appropriately provided near the lower electrode 21 where the void is likely to be generated, and thus, it is possible to more appropriately suppress the voltage applied to the void.

In the MIM capacitor 20 of the semiconductor device 1 according to the present embodiment, the surface of the lower electrode 21 in contact with the dielectric layer 22 is made of gold, and the dielectric layer 22 is formed to include a silicon nitride film. The surface of the lower electrode 21 in contact with the dielectric layer 22 is made of gold having low adhesion to the silicon nitride film constituting the dielectric layer 22, and thus, the void is easily generated in the region near the lower electrode 21 in the dielectric layer 22. However, since the floating electrode 50 described above is provided, the voltage applied to the void is appropriately suppressed, so that the occurrence of the partial discharge in the void can be appropriately suppressed.

In the MIM capacitor 20 of the semiconductor device 1 according to the present embodiment, when viewed from the stacking direction of the MIM capacitor 20, the region of the dielectric layer 22 includes the region of the lower electrode 21. By sufficiently increasing the region of the dielectric layer 22, it is possible to secure the electrode area in the MIM capacitor 20.

In the MIM capacitor 20 of the semiconductor device 1 according to the present embodiment, the floating electrode 50 is made of a material containing no gold. Since the floating electrode 50 is made of a material containing no gold having low adhesion to the dielectric layer 22, it is possible to suppress the generation of the void in the region in contact with the floating electrode 50 in the dielectric layer 22, and it is possible to suppress the occurrence of the partial discharge.

What is claimed is:

1. A semiconductor device comprising:
a metal insulator metal (MIM) capacitor configured to include a dielectric layer between a lower electrode and an upper electrode; and
a floating electrode provided in the dielectric layer, extended in parallel to the upper electrode and the lower electrode, and not electrically connected from any one of the lower electrode and the upper electrode.

2. The semiconductor device according to claim 1, wherein a distance between the floating electrode and the lower electrode is smaller than a distance between the floating electrode and the upper electrode.

3. The semiconductor device according to claim 2, wherein the distance between the floating electrode and the lower electrode is 1/10 or less of a thickness of the dielectric layer.

4. The semiconductor device according to claim 1,
wherein a surface of the lower electrode in contact with the dielectric layer is made of gold, and
wherein the dielectric layer is formed to include a silicon nitride film.

5. The semiconductor device according to claim 1, wherein, when viewed from a stacking direction of the MIM capacitor, a region of the dielectric layer includes a region of the lower electrode.

6. The semiconductor device according to claim 1, wherein the floating electrode is made of a material containing no gold.
